(19) United States
(12) Patent Application Publication
(10) Pub. No.: US 2024/0152052 A1
(43) Pub. Date: May 9, 2024

(54) SUBSTRATE PROCESSING APPARATUS

(71) Applicant: Tokyo Electron Limited, Tokyo (JP)

(72) Inventors: Masataka TANAKA, Kumamoto (JP); Tsunaki IKEDA, Kumamoto (JP); Yuta NISHIYAMA, Kumamoto (JP)

(21) Appl. No.: 18/386,781

(22) Filed: Nov. 3, 2023

(30) Foreign Application Priority Data
Nov. 9, 2022 (JP) 2022-179751

(51) Int. Cl. G03F 7/16; G03F 7/40; H01L 21/67

(52) U.S. Cl. CPC G03F 7/16; G03F 7/40; H01L 21/67023

(57) ABSTRACT

A substrate processing apparatus includes: a carrier block, into which a carrier storing a substrate is carried; a processing block including a liquid processing module that supplies a processing liquid to the substrate transferred from the carrier block, thereby performing a liquid processing; and an interface block, to which the substrate is transferred from the processing block. The interface block includes a liquid storage, in which a bottle storing the processing liquid is disposed. The carrier block includes a liquid feeder that feeds the processing liquid supplied from the liquid storage, to the liquid processing module. The liquid feeder includes a filter that filters the processing liquid supplied from the liquid storage, and a first pump that pumps the processing liquid toward the liquid processing module.

### CROSS-REFERENCE TO RELATED APPLICATIONS

This application is based on and claims priority from Japanese Patent Application No. 2022-179751, filed on Nov. 9, 2022, with the Japan Patent Office, the disclosure of which is incorporated herein in its entirety by reference.

### TECHNICAL FIELD

The present disclosure relates to a substrate processing apparatus.

### BACKGROUND

Japanese Patent Publication No. 2015-163401 discloses a fluid storage and distribution system, which includes a container with an inner volume, a liner provided in the inner volume and configured to confine a liquid medium using a zero or nearly zero headspace structure, and a dispensing assembly configured to be engaged with the container for the purpose of extracting the liquid medium from the liner during a dispensing operation. The fluid storage and distribution system further includes a built-in flow meter configured to monitor the liquid medium extracted from the liner during the dispensing operation, and generate an output related to an empty or nearly empty state of the liner when the state occurs.

### SUMMARY

According to an aspect of the present disclosure, a substrate processing apparatus includes: a carrier block into which a carrier storing a substrate is carried; a processing block including a liquid processing module that supplies a processing liquid to the substrate transferred from the carrier block, thereby performing a liquid processing; and an interface block to which the substrate is transferred from the processing block. The interface block includes a liquid storage in which a bottle storing the processing liquid is disposed. The carrier block includes a liquid feeder that feeds the processing liquid supplied from the liquid storage, to the liquid processing module. The liquid feeder includes a filter that filters the processing liquid supplied from the liquid storage, and a first pump that pumps the processing liquid toward the liquid processing module.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating a configuration of a coating and developing apparatus, which is a substrate processing apparatus, according to an embodiment of the present disclosure.

FIG. 2 is a view schematically illustrating a configuration of the center portion of the coating and developing apparatus in the depth direction.

FIG. 3 is a view schematically illustrating a configuration of a first stack processing block.

FIG. 4 is a view illustrating a location of a bottle cart provided with a liquid storage unit.

FIG. 5 is a view schematically illustrating a configuration of the bottle cart.

FIGS. 6A and 6B are views illustrating an entry and exit door.

FIG. 7 is a view illustrating an example of the location of the bottle cart.

FIGS. 8A and 8B are views schematically illustrating a configuration of a liquid feeding unit and a rotation mechanism of an electrical equipment box.

FIG. 9 is a view illustrating another example of the rotation mechanism of the electrical equipment box.

FIGS. 10A and 10B are views illustrating a slide mechanism of the electrical equipment box.

FIGS. 11A and 11B are views illustrating a slide mechanism of the liquid feeding unit.

FIG. 12 is a view schematically illustrating the configuration of the liquid feeding unit.

FIG. 13 is a view schematically illustrating a flow of a resist liquid from a liquid storage unit to a resist film forming module.

FIG. 14 is a view illustrating an example where another liquid storage unit is disposed above the bottle cart.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In a photolithography process performed when manufacturing semiconductor devices or the like, a series of processes is performed to form a predetermined resist pattern on a substrate such as a semiconductor wafer (hereinafter, referred to as “wafer”). The series of processes include, for example, a resist coating process for supplying a resist liquid onto a substrate to form a resist film, an exposure process for exposing the resist film, and a development process for supplying a developing solution to the exposed resist film to develop the resist film. The series of processes are performed by a coating and developing apparatus, which serves as a substrate processing apparatus equipped with, for example, various processing modules that process substrates and transfer mechanisms that transfer substrates, and connected to an exposure apparatus. The processing modules equipped in the coating and developing apparatus include a liquid processing module that performs a processing using a processing liquid such as a resist liquid, i.e., a liquid processing, on a substrate.

The processing liquid is supplied to the liquid processing module, from a liquid storage unit provided with a plurality of bottles that stores the processing liquid. The liquid storage unit is disposed, for example, outside or adjacent to the coating and developing apparatus.

Meanwhile, when a single coating and developing apparatus performs substrate processing with multiple specifications, the number of types of processing liquids used by the coating and developing apparatus increases, requiring a number of bottles that store the processing liquids. However, in a conventional liquid storage unit, the number of bottles that can be installed is limited, and thus, a sufficient number of bottles may not be installed. In this case, for example, a new liquid storage unit may be provided at a place adjacent to the coating and developing apparatus. However, when a new liquid storage unit is provided outside the coating and developing apparatus, the space occupied to install the coating and developing apparatus in a plant expands, which is not preferable from the viewpoint of space saving.

Thus, the technology of the present disclosure increases the number of bottles that may be used for the liquid processing on substrates, without installing a new liquid storage unit with bottles storing processing liquids outside the substrate processing apparatus.

Hereinafter, a substrate processing apparatus according to an embodiment of the present disclosure will be described with reference to the drawings. In the descriptions herein and the accompanying drawings, components having a substantially identical functional configuration will be denoted by the same reference numerals, and overlapping descriptions thereof will be omitted.

<Coating and Developing Apparatus>

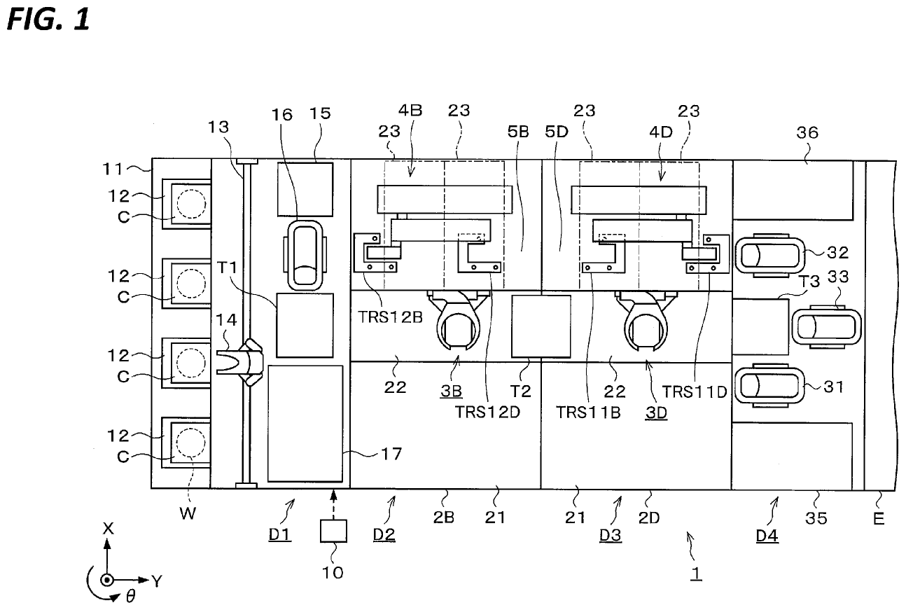

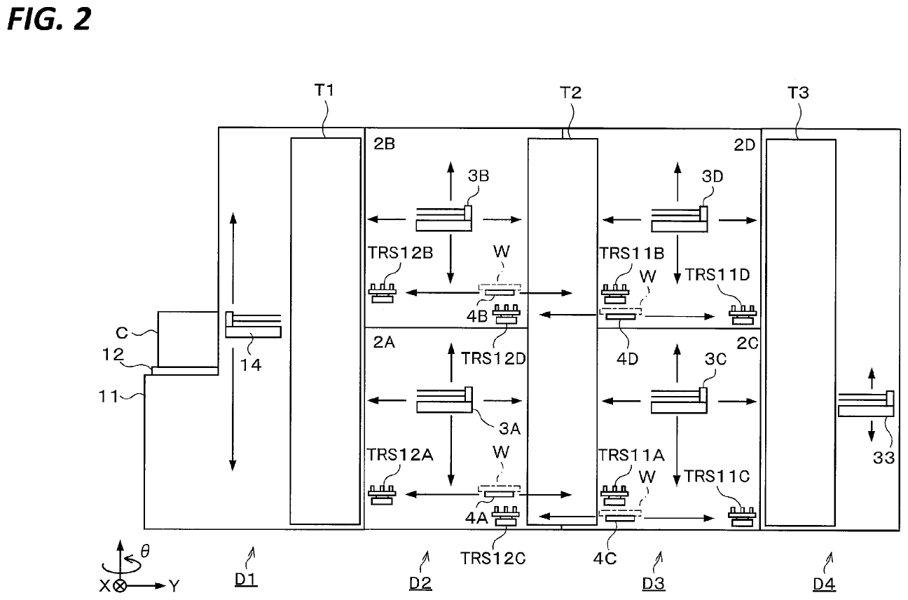

FIG. 1 is a plan view schematically illustrating a configuration of a coating and developing apparatus 1, which is a substrate processing apparatus. FIG. 2 is a view schematically illustrating a configuration of the center portion of the coating and developing apparatus 1 in the depth direction (e.g., X direction).

As illustrated in FIGS. 1 and 2, in the coating and developing apparatus 1, a carrier block D1, a first stack processing block D2, a second stack processing block D3, and an interface block D4 are arranged in this order in the width direction (e.g., Y direction). Among the carrier block D1, the first stack processing block D2, the second stack processing block D3, and the interface block D4, two adjacent blocks are connected to each other. The carrier block D1, the first stack processing block D2, the second stack processing block D3, and the interface block D4 each have a housing to be partitioned from each other, and each have a transfer region for wafers W, which are substrates, inside the housing.

An exposure apparatus E is connected to the opposite side of the interface block D4 to the second stack processing block D3 (e.g., on the positive side of the Y direction).

A wafer W is transferred to the coating and developing apparatus 1, in a state of being stored in a carrier C called, for example, a front opening unify pod (FOUP). Each of the first stack processing block D2 and the second stack processing block D3 is divided into two parts in the vertical direction. Each of the divided parts forms a processing block with processing modules and a main transfer mechanism that transfers wafers W with respect to the processing modules. Hereafter, in the first stack processing block D2 divided into two parts in the vertical direction, the lower part and the upper part will be referred to as a processing block 2A and a processing block 2B, respectively. In the second stack processing block D3 divided into two parts in the vertical direction, the lower part and the upper part will be referred to as a processing block 2C and a processing block 2D, respectively.

The processing blocks 2A and 2C are adjacent to each other in the width direction (e.g., Y direction), which is the horizontal direction, and may be together referred to as lower processing blocks. The processing blocks 2B and 2D are adjacent to each other in the width direction (e.g., Y direction), which is the horizontal direction, and may be together referred to as upper processing blocks. FIG. 1 illustrates the upper processing blocks. In each of the upper processing blocks 2B and 2D, a shuttle (also referred to as a bypass transfer mechanism) is provided. The shuttle transfers a wafer W toward the block on the downstream side of a transfer path in order not to pass through the processing modules.

A “module” is a location where a wafer W is placed, other than transfer mechanisms (including shuttles). A processing module refers to the module that performs a processing on a wafer W as described above, and the processing includes acquiring images for inspection.

The carrier block D1 is provided with a carrier placing table 11, for example, at the opposite end thereof to the first stack processing block D2 (e.g., on the negative side of the Y direction). On the carrier placing table 11, a plurality of placing boards 12 is arranged in the depth direction (e.g., X direction) to place carriers C thereon when the carriers C are carried into/out of the coating and developing apparatus 1.

Further, the carrier block D1 is provided with a delivery tower T1 at the end thereof on the side of the first stack processing block D2 (e.g., on the positive side of the Y direction) and at the center thereof in the depth direction (e.g., X direction). The delivery tower T1 is configured such that modules, such as delivery modules on which wafers W are temporarily placed, are stacked vertically in multiple tiers.

Further, the carrier block D1 is provided with a transfer mechanism 14 at the center thereof in the width direction (e.g., Y direction), which is the horizontal direction. The transfer mechanism 14 is movable on a transfer path 13 extending in the depth direction (e.g., X direction). The transfer mechanism 14 is also movable vertically and around the vertical axis (e.g., 0 direction), and may transfer wafers W between the carriers C on the placing boards 12 and the modules in the delivery tower T1.

Further, the carrier block D1 is provided with hydrophobization processing modules 15 at the rear end of the carrier block D1 behind the delivery tower T1 (e.g., on the positive side of the X direction), which perform a hydrophobization processing on wafers W. The hydrophobization processing modules 15 may be stacked vertically in multiple tiers.

Further, the carrier block D1 is provided with a transfer mechanism 16 between the delivery tower T1 and the hydrophobization processing modules 15. The transfer mechanism 16 is movable vertically and around the vertical axis (e.g., 0 direction), and may transfer wafers W, for example, between the modules inside the delivery tower T1 and the hydrophobization processing modules 15, and among the modules inside the delivery tower T1. The transfer mechanism 16 may also transfer a wafer W to a delivery module TRS 12B for a shuttle 4B in the processing block 2B.

The region in front of the delivery tower T1 (e.g., on the negative side of the X direction) in the carrier block D1 is an accommodation region 17 that accommodates a liquid feeding unit 50 to be described later.

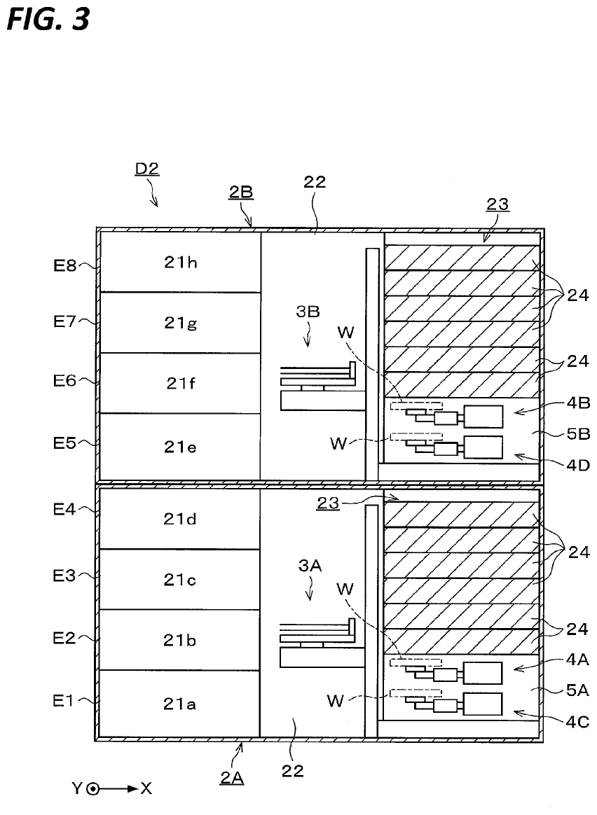

FIG. 3 is a view schematically illustrating the configuration of the first stack processing block D2. As illustrated in FIG. 3, resist film formation modules 21, which are liquid processing modules, are stacked in multiple tiers at the front part of the first stack processing block D2. Specifically, the front part of the first stack processing block D2 is divided vertically into a plurality of sections (e.g., four or more sections; eight sections in the example of FIG. 3), in which the resist film formation modules 21 (21a to 21h) are provided, respectively. Hereafter, the eight sections will be referred to as sections E1 to E8 in an order from the bottom. The lower sections E1 to E4 are included in the processing block 2A, and the upper sections E5 to E8 are included in the processing block 2B.

As illustrated in FIG. 3, a transfer region 22 for wafers W is provided behind the sections E5 to E8 of the processing block 2B (e.g., on the positive side of the X direction). In the width direction (e.g., Y direction), the transfer region 22 is formed in straight lines from one end to the other end of the processing block 2B in plan view. In the vertical direction, the transfer region 22 is formed over the sections E5 to E8. A processing module stack body 23 is provided behind the transfer region 22 (e.g., on the positive side of the X direction), in which processing modules are stacked in multiple tiers (seven tiers in the example of FIG. 3). Two processing module stack bodies 23 are provided to be spaced apart from each other, for example, in the width direction (e.g., Y direction). Each processing module stack body 23 includes heating modules 24 that perform a heating process, for example, to remove a solvent in a resist film on wafers W.

A main transfer mechanism 3B is provided in the transfer region 22. The main transfer mechanism 3B is movable in the width direction (e.g., Y direction), in the vertical direction, and around the vertical axis (e.g., 0 direction) as illustrated in FIG. 2, and may transfer a wafer W with respect to each processing module in the processing block 2B. The main transfer mechanism 3B may transfer wafers W with respect to modules positioned at the same height as the processing block 2B among the modules in the delivery tower T1 and a delivery tower T2 to be described later, which are adjacent to the processing block 2B in the width direction (e.g., Y direction). The main transfer mechanism 3B may also transfer wafers W with respect to the delivery module TRS for the shuttle 4B in the processing block 2B.

As illustrated in FIG. 3, a partitioned flat space 5B is provided below the processing module stack body 23 of the processing block 2B. The space 5B is formed from one end to the other end of the processing block 2B in the width direction (e.g., Y direction). In the space 5B, the shuttle 4B and shuttle delivery modules TRS 12B and TRS 12D illustrated in FIG. 2 are provided.

The processing blocks 2A, 2C, and 2D have the same configuration as that of the processing block 2B, except for differences to be described later. Each of the processing blocks 2A, 2C, and 2D includes a main transfer mechanism corresponding to the main transfer mechanism 3B. In the descriptions and the drawings hereinafter, the main transfer mechanisms of the processing blocks 2A, 2C, and 2D will be denoted using the same alphabets as those of the processing blocks 2A, 2C, and 2D, instead of “B.” Specifically, the main transfer mechanism of the processing block “2A” will be denoted by “3A.” The other main transfer mechanisms 3A, 3C, and 3D corresponding to the main transfer mechanism 3B may also transfer wafers W with respect to the processing modules in the processing blocks where the main transfer mechanisms 3A, 3C, and 3D are provided, respectively, the delivery modules TRS for a shuttle, and the delivery towers adjacent to each of the processing blocks in the width direction (e.g., Y direction).

Similarly, each space corresponding to the space 5B, where a shuttle may be installed, will be denoted using the same alphabet as that of the corresponding processing block, instead of “B.” When a shuttle is provided in a processing block, the shuttle will also be denoted using the same alphabet as that of the processing block. The delivery modules TRS for a shuttle will also be denoted using the same alphabet as that of the processing block where the shuttle is provided. Of the delivery modules TRS used for the same shuttle, the delivery module close to the interface block D4 will be denoted including the numeral “11,” and the delivery module close to the carrier block D1 will be denoted including the numeral “12.” Specifically, for example, the shuttle provided in the processing block 2D will be denoted by “4D,” the delivery module for the shuttle 4D on the side of the interface block D4 will be denoted by “TRS 11D,” and the delivery module for the shuttle 4D on the side of the carrier block D1 will be denoted by “TRS 12D.”

The processing block 2A is different from the processing block 2B in that the transfer region 22 of the processing block 2A is formed vertically over the sections E1 to E4.

The second stack processing block D3 illustrated in FIG. 2 has substantially the same configuration as that of the first stack processing block D2. Hereinafter, descriptions will be made on the second stack processing block D3, focusing on the differences from the first stack processing block D2.

The processing block 2D is identical to the processing block 2B in terms of the position relationship among the transfer region 22, the processing module stack body 23, the main transfer mechanism, and the space where the shuttles stacked on the processing modules are installed. Meanwhile, in the sections E5 to E8 of the processing block 2D, developing modules are provided to develop wafers W with a developing solution. While heating modules are also provided in the processing module stack body 23 of the processing block 2D, the heating modules are used for post exposure bake (PEB). Further, in the processing module stack body 23 of the processing block 2D, an inspection module is provided, which captures images of wafers W to determine an abnormality of wafers W (i.e., acquires images of wafers W for the purpose of inspecting the wafers W). The space 5D for a shuttle in the processing block 2D is positioned at the same height as the space 5B, and communicates with the space 5B. In the space 5D, the shuttle 4D and the delivery modules TRS 11B and TRS 11D for the shuttle are provided.

The processing block 2C is different from the processing block 2D in that the transfer region 22 of the processing block 2C is formed vertically over the sections E1 to E4, as in the processing block 2A illustrated in FIG. 3.

The delivery tower T2 is provided at the end of the transfer region 22 of the second stack processing block D3 on the side of the first stack processing block D2 (e.g., on the negative side of the Y direction). The delivery tower T2 is disposed to partially span over the end of the transfer region 22 of the first stack processing block D2 on the side of the first stack processing block D3 (e.g., on the positive side of the Y direction). The delivery tower T2 is configured with modules stacked vertically in multiple tiers, such as delivery modules.

As illustrated in FIG. 1, the interface block D4 includes a delivery tower T3 at the center thereof in the depth direction (e.g., X direction). The delivery tower T3 is configured with modules stacked vertically in multiple tiers, such as delivery modules. Transfer mechanisms 31, 32, and 33 are provided in front of the delivery tower T3 (e.g., on the negative side of the X direction), behind the delivery tower T3 (e.g., on the positive side of the X direction), and beside the delivery tower T3 on the side of the exposure apparatus E (e.g., on the positive side of the Y direction), respectively. The transfer mechanisms 31, 32, and 33 are movable vertically and around the vertical axis (e.g., 0 direction).

A peripheral exposure module 35 is provided in front of the transfer mechanism 31 (e.g., on the negative side of the X direction) to perform an exposure processing on the peripheral edge of a wafer W with a resist film formed thereon. A post-exposure cleaning module 36 is provided behind the transfer mechanism 32 (e.g., on the positive side of the X direction) to supply a cleaning liquid to the surface of a wafer W after the exposure. The peripheral exposure module 35 and the post-exposure cleaning module 36 may be stacked vertically in multiple tiers. Further, the peripheral exposure module 35 may be disposed at the rear side of the interface block D4 (e.g., on the positive side of the X direction), and the post-exposure cleaning module 36 may be disposed at the front side of the interface block D4 (e.g., on the negative side of the X direction).

Each of the transfer mechanisms 31 to 33 may transfer wafers W with respect to the modules in the delivery tower T3. Further, the transfer mechanism 31 may transfer a wafer W with respect to the peripheral exposure module 35, the transfer mechanism 32 may transfer a wafer W with respect to the post-exposure cleaning module 36, and the transfer mechanism 33 may transfer a wafer W with respect to the exposure apparatus E.

A liquid storage unit is provided in front of the delivery tower T3 in the depth direction (e.g., on the negative side of the X direction), which stores a resist liquid to be supplied to the resist film forming module 21 serving as a liquid processing module. The liquid storage unit will be described in detail later.

Here, the shuttles 4B and 4D and the delivery modules TRS for each shuttle are described below.

The shuttle 4B transfers a wafer W from the processing block 2D toward the carrier block D1. As illustrated in FIG. 2, of the delivery modules TRS 11B and TRS 12B for the shuttle 4B, the delivery module TRS 12B is provided at the end of the space 5B on the side of the carrier block D1 (e.g., on the negative side of the Y direction) to deliver a wafer W with respect to the transfer mechanism 14 of the carrier block D1. The delivery module TRS 11B is provided at the end of the space 5D on the side of the processing block 2B (e.g., on the negative side of the Y direction), which is closer to the interface block D4 (e.g., on the positive side of the Y direction) than the delivery tower T2 is, to delivery a wafer W with respect to the main transfer mechanism 3D of the processing block 2D.

The shuttle 4D transfers a wafer W from the processing block 2B toward the interface block D4. Of the delivery modules TRS 11D and TRS 12D for the shuttle 4D, the delivery module TRS 11D is provided at the end of the space 5D on the side of the interface block D4 (e.g., on the positive side of the Y direction) to deliver a wafer W with respect to the transfer mechanism 32 of the interface block D4. The delivery module TRS 12D is provided at the end of the space 5B on the side of the processing block 2D (e.g., on the positive side of the Y direction), which is closer to the carrier block D1 (e.g., on the negative side of the Y direction) than the delivery tower T2 is, to deliver a wafer W with respect to the main transfer mechanism 3B of the processing block 2B.

The shuttle 4A transfers a wafer W from the processing block 2C toward the carrier block D1. The positions of the delivery modules TRS 11A and TRS 12A for the shuttle 4A are the same as those of the delivery modules TRS 11B and TRS 12B for the shuttle 4B.

The shuttle 4C transfers a wafer W from the processing block 2A toward the interface block D4. The positions of the delivery modules TRS 11C and TRS 12C for the shuttle 4C are the same as those of the delivery modules TRS 11D and TRS 12D for the shuttle 4B.

As illustrated in FIG. 1, the coating and developing apparatus 1 includes a control unit 10. The control unit 10 is a computer provided with, for example, a processor such as a central processing unit (CPU) and a memory, and includes a program storage unit (not illustrated) that stores programs including commands to be executed by the processor. The program storage unit stores programs including commands to control, for example, operations of drive systems of the various processing modules and transfer mechanisms described above and an operation of supplying a resist liquid to a wafer W to be described later, thereby performing a wafer processing to be described later. The programs may be stored in a computer-readable storage medium, and may be installed into the control unit from the storage medium. The storage medium may be a temporary or non-temporary storage medium.

<Wafer Processing>

Next, descriptions will be made on an example of a wafer processing method that uses the coating and developing apparatus 1.

For example, as illustrated in FIG. 1, first, the transfer mechanism 14 takes a wafer W out of a carrier C that has been carried into the carrier block D1 of the coating and developing apparatus 1 and placed on a placing board 12, and transfers the wafer W to a delivery module of the delivery tower T1.

Then, the transfer mechanism 16 transfers the wafer W to a hydrophobization processing module 15, and a hydrophobization processing is performed on the wafer W. Then, the transfer mechanism 16 returns the wafer W to the delivery tower T1.

Subsequently, the main transfer mechanism 3A or 3B illustrated in FIG. 3 transfers the wafer W to a resist film formation module 21→a heating module 24 in this order in the first stack processing block D2, so that a resist film is formed on the wafer W. After the formation of the resist film, the main transfer mechanism 3A or 3B transfers the wafer W to a delivery module of the delivery tower T2 illustrated in FIG. 2, and then, the main transfer mechanism 3C or 3D transfers the wafer W to a delivery module of the delivery tower T3 of the interface block D4. After the formation of the resist film, the wafer W may be transferred from the processing block 2A to the delivery tower T3 while bypassing the second stack processing block D3 through the main transfer mechanism 3A, the shuttle 4C, the delivery modules TRS 12C and TRS 11C, and the transfer mechanism 32 (e.g., FIG. 1). Further, after the formation of the resist film, the wafer W may be transferred from the processing block 2B to the delivery tower T3 while bypassing the second stack processing block D3 through the main transfer mechanism 3B, the shuttle 4D, the delivery modules TRS 12D and TRS 11D, and the transfer mechanism 32.

Then, the transfer mechanism 31 transfers the wafer W to the peripheral exposure module 35, and an exposure processing is performed on the peripheral edge of the wafer W. Thereafter, the transfer mechanism 31 returns the wafer W to the delivery tower T3, and then, the transfer mechanism 33 transfers the wafer W to the exposure apparatus E so that an exposure processing is performed. After the exposure, the transfer mechanism 33 transfers the wafer W to the delivery tower T3, and then, the transfer mechanism 32 transfers the wafer W to the post-exposure cleaning module 36 so that a cleaning is performed.

After the cleaning by the post-exposure cleaning module 36, for example, the transfer mechanism 32 returns the wafer W to the delivery tower T3. Then, the main transfer mechanism 3C or 3D transfers the wafer W to a heating module→a developing module→an inspection module in this order in the second stack processing block D3, so that a resist pattern is formed after a PEB processing, and then, an abnormality of the wafer W is determined. Subsequently, the main transfer mechanism 3C or 3D illustrated in FIG. 2 returns the wafer W to the delivery tower T2, and then, the main transfer mechanism 3A or 3B returns the wafer W to the delivery tower T1. The wafer W processed by the inspection module may be transferred from the processing block 2C to the delivery tower T1 while bypassing the first stack processing block D2 through the main transfer mechanism 3C, the shuttle 4A, the delivery modules TRS 11A and TRS 12A, and the transfer mechanism 16. Further, the wafer W processed by the inspection module may be transferred from the processing block 2D to the delivery tower T1 while bypassing the first stack processing block D2 through the main transfer mechanism 3D, the shuttle 4B, the delivery modules TRS 11B and TRS 12B, and the transfer mechanism 16.

Then, the transfer mechanism 14 returns the wafer W to the carrier C from the delivery tower T1. In this way, the series of process for the wafer processing by the coating and developing apparatus 1 are completed.

<Bottle Cart>

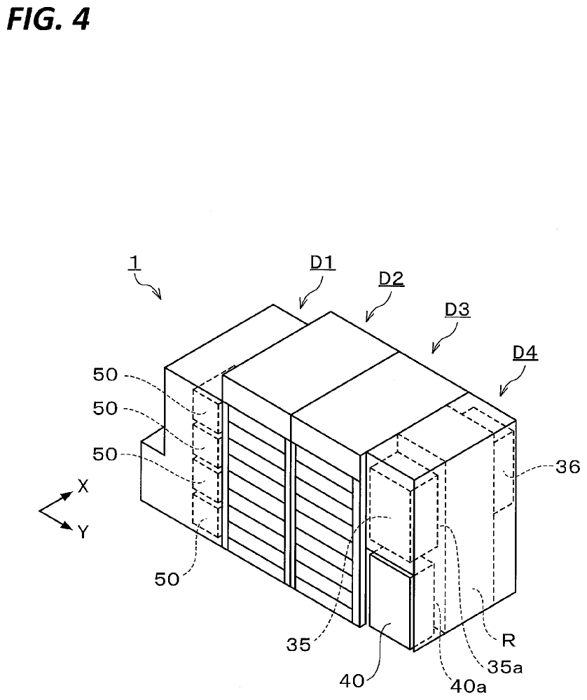

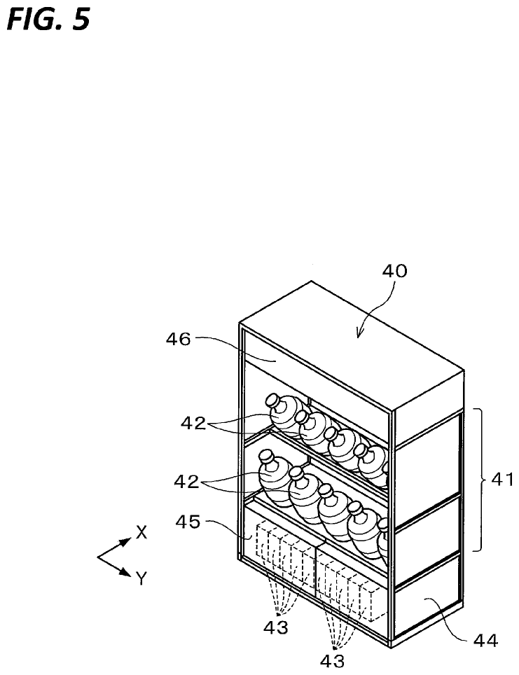

Next, descriptions will be made on a bottle cart provided with the liquid storage unit that stores the resist liquid to be supplied to the resist film formation module 21. FIG. 4 is a view illustrating a position of a bottle cart 40 provided with the liquid storage unit. FIG. 5 is a view schematically illustrating the configuration of the bottle cart 40. While the bottle cart 40 may be carried by an operator, the illustration of wheels and a handle of the bottle cart 40 is omitted.

As illustrated in FIG. 4, the bottle cart 40 is disposed at the front side of the interface block D4 in the depth direction (e.g., on the negative side of the X direction). The peripheral exposure module 35 described above is disposed above the bottle cart 40, and a transfer region R is present behind the bottle cart 40 in the depth direction (e.g., on the positive side of the X direction), which includes the region where the delivery tower T3 is disposed and the transfer mechanisms 31 to 33 are movable as illustrated in FIG. 1.

In the interface block D4, the rear end 40a of the bottle cart 40 in the depth direction (e.g., X direction) (e.g., on the side of the transfer region R) may be positioned further forward (e.g., on the opposite side to the transfer region R) than the rear end 35a of the peripheral exposure module 35. As a result, the transfer region R may not be narrowed by the bottle cart 40.

As illustrated in FIG. 5, the bottle cart 40 is a multi-tiered cart that includes, for example, four layered spaces, and the liquid storage unit 41 is provided in the bottle cart 40 as a supply source of the resist liquid. The liquid storage unit 41 is a region where a plurality of bottles 42 (e.g., 10 bottles) that each stores the resist liquid as a processing liquid is arranged. In the example illustrated in FIG. 5, the liquid storage unit 41 corresponds to the two central layered spaces in which the plurality of bottles 42 are arranged horizontally in rows.

In the liquid storage unit 41, for example, several bottles 42 storing the same type of resist liquid and several bottles 42 storing other types of resist liquids are arranged in an appropriate combination, so that a plurality of types of resist liquids may be used separately according to product specifications. Further, a plurality of bottles 42 that stores different types of resist liquids may be arranged in the liquid storage unit 41. For example, when ten bottles 42 storing different types of resist liquids are arranged in the liquid storage unit 41, ten different types of resist liquids may be supplied from the liquid storage unit 41.

A plurality of assist pumps 43 is arranged as second pumps below the liquid storage unit 41, i.e., in the lowest layered space of the bottle cart 40. The assist pumps 43 are provided to pump the resist liquid stored in the bottles 42 to the liquid feeding unit 50 to be described later. The assist pumps 43 are configured with, for example, diaphragm pumps, which are variable displacement pumps. The plurality of assist pumps 43 are connected to the plurality of bottles 42, respectively, via pipes (not illustrated), and one assist pump 43 is connected to one bottle 42.

The assist pumps 43 may be configured to not only pump the resist liquid but also aspirate the resist liquid. Further, the assist pumps 43 may be provided as needed, and may not be provided as long as the resist liquid may be sent from the bottles 42 to the liquid feeding unit 50 to be described later.

The three peripheral sides of the region storing the assist pumps 43 are covered by a wall 44, and a door 45 serving as a cover is attached to the front side of the region (e.g., on the negative side of the X direction). The door 45 is configured with, for example, left/right double doors. When the door 45 is opened, the region storing the assist pumps 43 is opened to the outside of the bottle cart 40, and when the door 45 is closed, the region is closed.

When the door 45 is installed to be openable/closable as described above, the door 45 may be opened only at necessary time, for example, at the time when a maintenance work is performed on the assist pumps 43, and may be closed during a resist film formation process. This may suppress the occurrence of a failure in the operation of the assist pumps 43, which may be caused, for example, when the operator inadvertently touches the assist pumps 43 and the peripheral parts thereof.

Meanwhile, when a failure occurs in the operation of the assist pumps 43, the resist liquid supply system may malfunction, which may adversely affect the resist film formation process. Thus, at the case where the door 45 is provided, an opening/closing detection sensor (not illustrated) may be provided to detect the opening/closing of the door 45. As for the opening/closing detection sensor, for example, a known sensor such as a magnetic sensor or an infrared sensor may be used. When the opening/closing detection sensor detects that the door 45 is opened, the control unit 10 (e.g., FIG. 1) may perform a control to stop the supply of the resist liquid to the resist film formation module 21.

As for a specific example of the control for stopping the supply of the resist liquid, a control may be performed to shut off the supply of power to the assist pumps 43 or switch any one of valves on a resist liquid supply path reaching the resist film formation module 21 to a closed state. In this way, the supply of the resist liquid is automatically stopped when the doors 45 are opened, which may prevent the occurrence of defects in the formation of the resist film caused from the supply of the resist liquid.

In the descriptions above, the door 45 is described as an example of the cover. However, the cover may be, for example, a lid body (not illustrated) removably attached to the bottle cart 40. In this case, the above-described detection sensor, which serves as a detection unit, is disposed to detect the mounted state of the cover. When it is detected that the cover is in a non-mounted state, the control to stop the supply of the resist liquid is performed.

The “mounted state” refers to a state where the region storing the assist pumps 43 is covered. For example, when the cover is a door, the “mounted state” indicates a state where the door is closed, and when the cover is a lid body, the “mounted state” indicates a state where the lid body is attached to the bottle cart 40. Meanwhile, the “non-mounted state” refers to a state where a portion of the region storing the assist pumps 43 is exposed to the outside of the bottle cart 40. For example, when the cover is a door, the “non-mounted state” indicates a state where the door is opened, and when the cover is a lid body, the “non-mounted state” indicates a state where the lid body is removed from the bottle cart 40.

Above the liquid storage unit 41, i.e., in the uppermost layered space of the bottle cart 40, a storage container 46 is provided to store electrical components for operating the assist pumps 43.

Although not illustrated, a removable cover (not illustrated) is attached to the front side of the bottle cart 40 (e.g., on the negative side of the X direction), to cover the front sides of the bottles 42 of the liquid storage unit 41 and the storage container 46.

Further, the bottle cart 40 may be provided with a buffer tank (not illustrated) that temporarily stores the resist liquid of the bottles 42 when necessary. In this case, the bottles 42, the buffer tank, and the assist pumps 43 are arranged in this order from the upstream side in the resist liquid supply path.

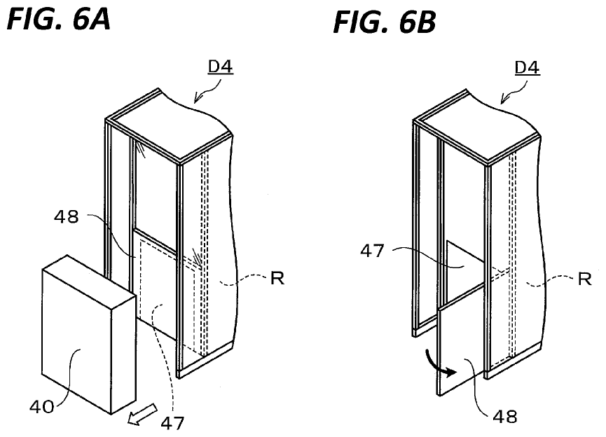

The bottle cart 40 described above is fixed to the interface block D4 not to move during the resist film formation process. Meanwhile, for example, when a work for replacing the bottles 42 or other maintenance works are performed, the bottle cart 40 is drawn out of the interface block D4 as illustrated in FIG. 6A as necessary. FIGS. 6A and 6B do not illustrate the peripheral exposure module 35.

After the bottle cart 40 is drawn out and a desired work is completed, the bottle cart 40 is returned to a predetermined fixed position inside the interface block D4, and the bottle cart 40 is fixed thereto.

The interface block D4 may be provided with a detection unit (not illustrated) that detects the movement of the bottle cart 40 from the predetermined fixed position. In this case, for example, when the detection unit detects that the bottle cart 40 moves during the resist film formation process, a control may be performed to report the movement of the bottle cart 40, such as giving a warning sound.

As illustrated in FIG. 6A, behind the bottle cart 40, an entry/exit port 47 is provided such that the operator enters and exits the transfer region R, and an openable/closeable entry/exit door 48 is provided to cover the entry/exit port 47. At the case where the entry/exit door 48 is provided behind the bottle cart 40, the operator draws the bottle cart 40 forward as illustrated in FIG. 6A when performing a maintenance work inside the transfer region R. Then, the operator opens the entry/exit door 48 as illustrated in FIG. 6B, and enters the transfer region R through the entry/exit door 47 to perform a predetermined work. After completing the work, the operator exits the transfer region R, closes the entry/exit door 48, and returns the bottle cart 40 to the predetermined fixed position in the interface block D4.

When the operator enters the transfer region R, the operations of the transfer mechanisms 31 to 33 (e.g., FIG. 1) are stopped in advance. Meanwhile, for example, the transfer mechanisms 31 to 33 may be configured to be automatically stopped when the entry/exit door 48 is opened during the operations of the transfer mechanisms 31 to 33.

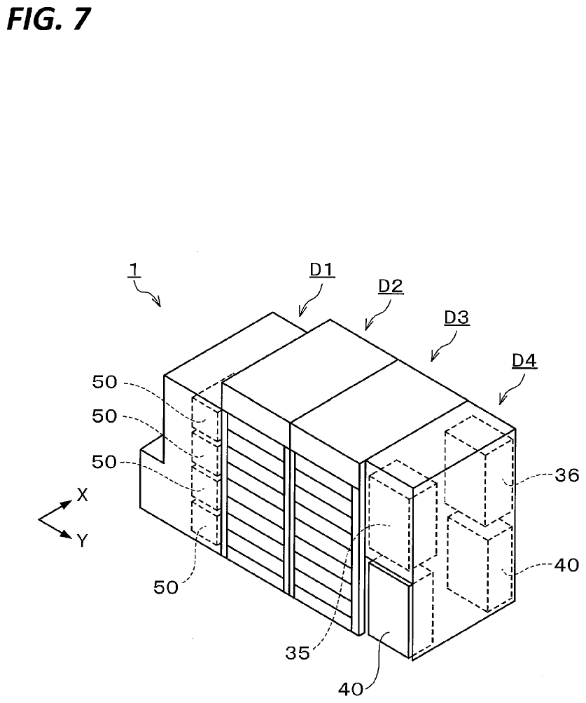

In the descriptions above, the bottle cart 40 is disposed at the front end of the interface block D4 (e.g., on the negative side of the X direction). However, for example, the bottle cart 40 may be disposed at the rear side of the interface block D4 (e.g., on the positive side of the X direction) as illustrated in FIG. 7.

That is, the bottle cart 40 may be disposed at one end (e.g., front or rear end) of the interface block D4, or at both ends (e.g., front and rear ends) of the interface block D4, in the depth direction (e.g., X direction). In the plan view of the coating and developing apparatus 1, the depth direction (e.g., X direction) may be expressed as the direction perpendicular to the direction, in which a wafer W is transferred between a processing block such as the first stack processing block D2 or the second stack processing block D3 and the interface block D4.

<Liquid Feeding Unit>

Next, the liquid feeding unit 50 that supplies the resist liquid to the resist film formation module 21 will be described. The liquid feeding unit 50 is disposed in the accommodation region 17 inside the carrier block D1 illustrated in FIG. 1. As illustrated in FIGS. 4 and 7, a plurality of liquid feeding units 50 (e.g., four liquid feeding units 50) is arranged along the vertical direction.

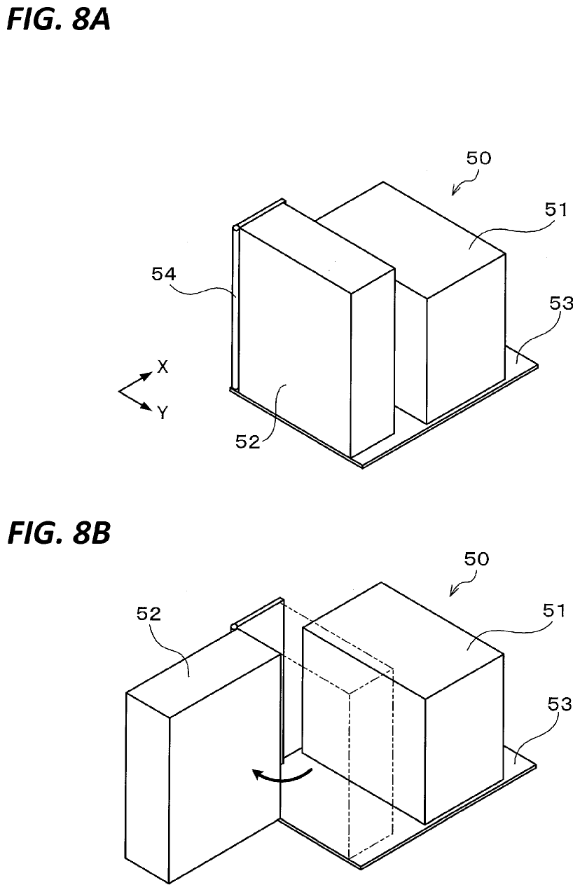

FIGS. 8A and 8B are views schematically illustrating the configuration of each liquid feeding unit 50. As illustrated in FIG. 8A, the liquid feeding unit 50 includes a liquid feeder 51, to which the resist liquid is supplied from the liquid storage unit 41, an electrical equipment box 52 that stores electrical components for operating the liquid feeder 51, and a rectangular base 53, to which the liquid feeder 51 and the electrical equipment box 52 are fixed.

The electrical equipment box 52 is disposed in front of the liquid feeder 51, i.e., at the front side of the carrier block D1 (e.g., FIG. 4) in the depth direction (e.g., on the negative side of the X direction). In the plan view of the coating and developing apparatus 1, the depth direction (e.g., X direction) may be expressed as the direction perpendicular to the direction, in which a wafer W is transferred between a processing block such as the first stack processing block D2 or the second stack processing block D3 and the carrier block D1.

The liquid feeding unit 50 includes a rotation axis 54 that extends vertically to serve as a mechanism for pivoting the electrical equipment box 52. The rotation axis 54 and the electrical equipment box 52 are fixed to each other at the corner of the front side of the base 53 (e.g., on the negative side of the X direction). Thus, as illustrated in FIG. 8B, the electrical equipment box 52 is pivotable forward (e.g., toward the negative side of the X direction) about the rotation axis 54.

When the mechanism for pivoting the electrical equipment box 52 is provided, the electrical equipment box 52 alone may be pivoted forward (e.g., toward the negative side of the X direction) in a state where the liquid feeding unit 50 is fixed at a predetermined fixed position inside the carrier block D1. Thus, the maintenance work for the electrical components may be performed without removing the liquid feeding unit 50 from the carrier block D1.

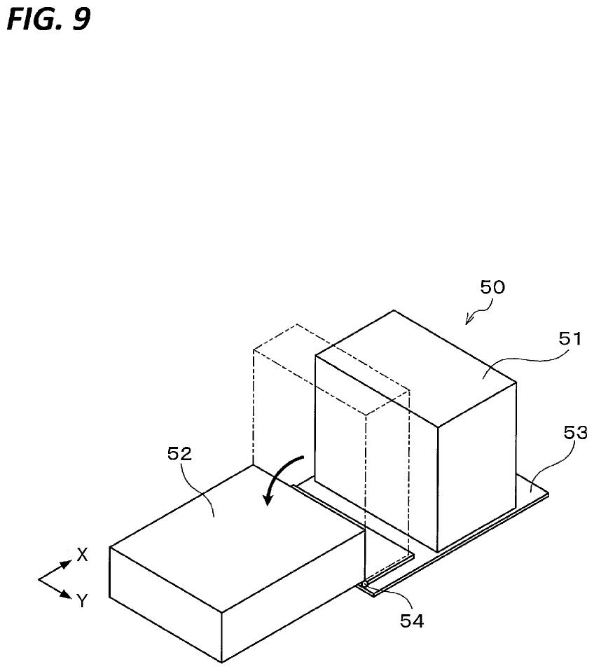

As illustrated in FIG. 9, for example, the rotation axis 54 may be provided to extend along the width direction of the carrier block D1 (e.g., Y direction). In this case as well, the electrical equipment box 52 may be pivoted by being tilted over forward (e.g., toward the negative side of the X direction), so that the maintenance work for the electrical components may easily be performed.

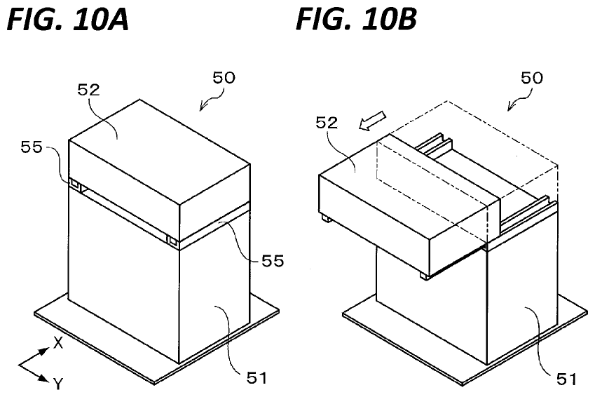

As illustrated in FIG. 10A, the electrical equipment box 52 may be disposed above the liquid feeder 51. In this case, as a mechanism for slide moving the electrical equipment box 52 forward, rails 55 may be provided at the bottom of the electrical equipment box 52 to extend along the depth direction (e.g., the X direction). Accordingly, as illustrated in FIG. 10B, the electrical equipment box 52 may be drawn out forward (e.g., toward the negative side in the X direction), so that the maintenance work for the electrical components may easily be performed.

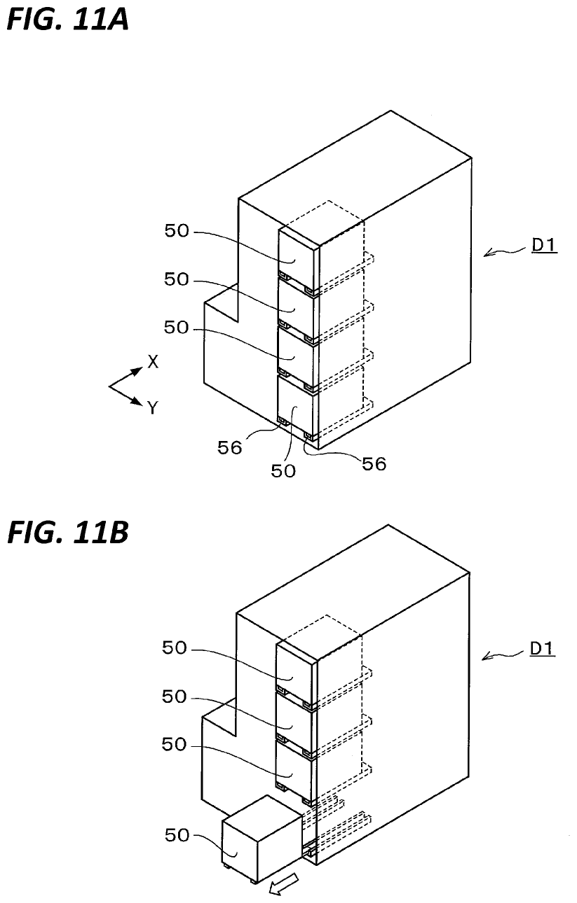

Further, as illustrated in FIG. 11A, as a mechanism for slide moving each liquid feeding unit 50 itself, rails 56 may be provided at the bottom of the liquid feeding unit 50 to extend along the depth direction (e.g., X direction). Accordingly, for example, only a malfunctioning liquid feeding unit 50 may be drawn out from the carrier block D1 to perform a work such as maintenance or replacement of parts. While the work is being performed, the remaining liquid feeding units 50 in the carrier block D1 may feed the resist liquid as usual, so that the resist film formation process may be continuously performed using the remaining liquid feeding units 50.

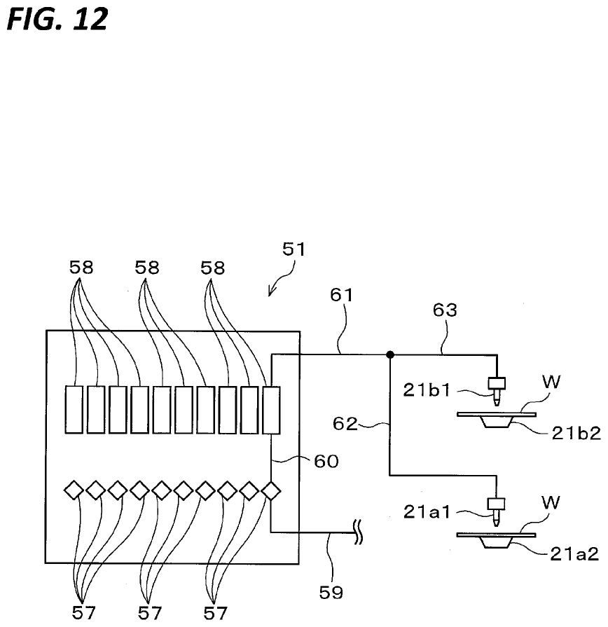

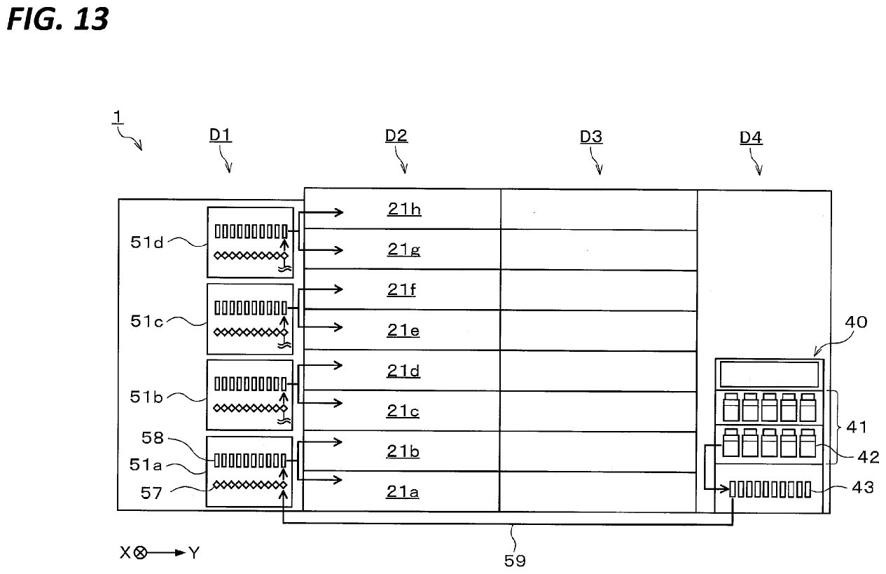

Next, the configuration of the liquid feeder 51 will be described. FIG. 12 is a view schematically illustrating the configuration of the liquid feeder 51. FIG. 13 is a view schematically illustrating the flow of the resist liquid from the liquid storage unit 41 to the resist film formation module 21.

While the drawings referenced hereinafter do not illustrate various valves, foreign matter detection sensors and others provided in the resist liquid supply path, the various valves, the foreign matter detection sensors and others may be appropriately provided within the range that does not interfere with the function of supplying the resist liquid, which will be described later.

As illustrated in FIG. 12, the liquid feeder 51 includes a filter 57 that filters the resist liquid, and a dispense pump 58, which is a first pump. A plurality of filters 57 (e.g., ten filters in the example of FIG. 12) and a plurality of dispense pumps 58 (e.g., ten dispense pumps in the example of FIG. 12) are provided. The dispense pump 58 is, for example, a diaphragm pump, which is variable displacement pump. The dispense pump 58 may be configured to not only pump the resist liquid but also aspirate the resist liquid.

The resist liquid pumped by each assist pump 43 described above reaches the filter 57 through a pipe 59. Then, the dispense pump 58 pumps the resist liquid filtered by the filter 57 to the downstream side thereof through a pipe 60. A pipe 61 connected to the downstream side of the dispense pump 58 branches into pipes 62 and 63. The downstream end of the pipe 62 is connected to an ejection nozzle 21a1 that serves as an ejection unit, and the downstream end of the pipe 63 is connected to an ejection nozzle 21b1 that serves as an ejection unit.

The ejection nozzle 21a1 ejects the resist liquid onto a wafer W held on a spin chuck 21a2 that serves as a substrate holding unit, and the ejection nozzle 21b1 ejects the resist liquid onto a wafer W held on a spin chuck 21b2 that serves as a substrate holding unit.

While FIG. 12 illustrates only the pipes connected to one filter 57 and one dispense pump 58 among the plurality of filters 57 and the plurality of dispense pumps 58, pipes are similarly connected to the other filters 57 and dispense pumps 58. Further, the pipes connected to the upstream sides of the filters 57 are connected to the different bottles 42, respectively. Thus, the resist liquids pumped by the dispense pumps 58 are supplied from the different bottles 42, respectively. The pipe extending from each dispense pump 58 is configured to switch the state of connection to the pipes 62 and 63 that supply the resist liquid to the ejection nozzles 21a1 and 21b1, respectively.

In the liquid feeder 51 having the piping configuration described above, the resist liquid may be ejected from each of the ejection nozzles 21a1 and 21b1 by switching the resist liquid supply source as necessary. For example, when one liquid feeder 51 includes, for example, ten filters 57 and ten dispense pumps 58, ten resist liquid supply systems are provided, so that a system to be used may be switched according to product specifications.

The spin chuck 21a2 described above is disposed in the resist film formation module 21a illustrated in FIG. 13, and the spin chuck 21b2 is disposed in the resist film formation module 21b illustrated in FIG. 13. That is, one liquid feeder 51 supplies the resist liquid to two different resist film formation modules 21. In the example illustrated in FIG. 13, among four liquid feeders 51a to 51d, the lowest liquid feeder 51a supplies the resist liquid to the resist film formation modules 21a and 21b disposed in the two layered spaces from the bottom in the first stack processing block D2.

The other liquid feeders 51b to 51d have the same configuration as the liquid feeder 51a. The liquid feeder 51b supplies the resist liquid to the resist film formation modules 21c and 21d, the liquid feeder 51c supplies the resist liquid to the resist film formation modules 21e and 21f, and the liquid feeder 51d supplies the resist liquid to the resist film formation modules 21g and 21h.

The supply sources of the resist liquid supplied to the liquid feeders 51a to 51d may be the bottles 42 provided in the liquid storage unit 41 of the bottle cart 40, or bottles of a conventional liquid storage unit (not illustrated) provided outside the coating and developing apparatus 1 separately from the liquid storage unit 41 of the bottle cart 40.

When the supply sources of the resist liquid supplied to the liquid feeders 51a to 51d are different, the pipe lengths from the supply sources of the resist liquid to the liquid feeders 51a to 51d are also different. However, it is preferable to make the pipe length constant, which extends from the ejection nozzle of each of the resist film formation modules 21a to 21h to the filter of each of the liquid feeders 51a to 51d disposed in the supply path through which the resist liquid is supplied to the corresponding ejection nozzle.

For example, the pipe length from the filter 57 to the ejection nozzle 21a1 (e.g., the total length of the pipes 60, 61, and 62) illustrated in FIG. 12 may be the same as the pipe length from the same filter 57 to the ejection nozzle 21b1 (e.g., the total length of the pipes 60, 61, and 63). This facilitates ensuring the uniform cleanness of the resist liquid supplied from each of the ejection nozzles 21a1 and 21b1, and also ensuring the uniform quality of the resist films formed by the two different resist film formation modules 21a and 21b.

The coating and developing apparatus 1 according to an embodiment of the present disclosure has been described.

In the coating and developing apparatus 1, the bottle cart 40 including the liquid storage unit 41 is disposed inside the interface block D4. As a result, without newly providing a conventional liquid storage unit (not illustrated) outside the coating and developing apparatus 1, the number of bottles usable for the resist film formation process on wafers W may be increased. Further, while reducing the space occupied for installing the coating and developing apparatus 1 in a plant, more various types of resist liquids may be supplied than those of the conventional apparatus.

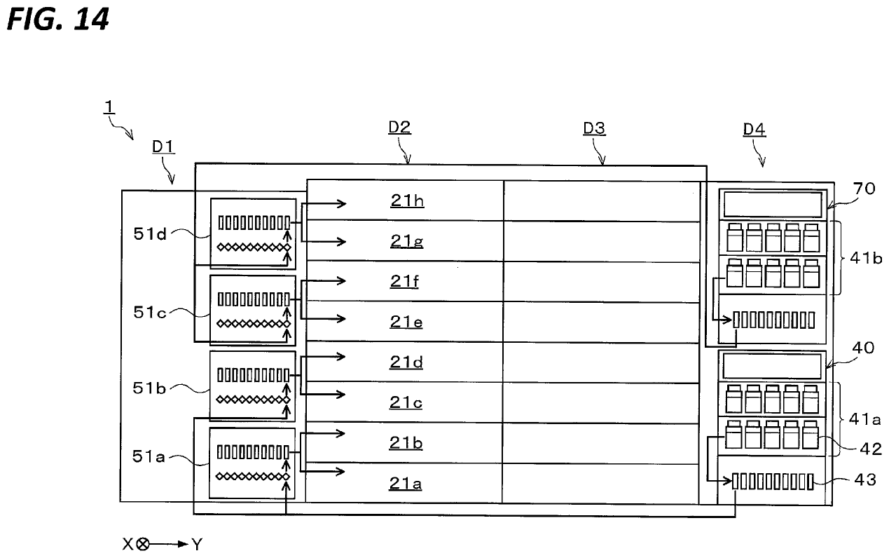

Further, according to the arrangement of the various processing modules in the coating and developing apparatus 1, for example, an additional liquid storage unit 41b may be provided above the bottle cart 40 including a liquid storage unit 41a as illustrated in FIG. 14. In this case, for example, the resist liquid is supplied from the liquid storage unit 41a disposed at the lower part of the interface block D4 to the two liquid feeder M a and 51b from the bottom in the carrier block D1. Further, for example, the resist liquid is supplied from the liquid storage unit 41b disposed on the upper part of the interface block D4 to the two liquid feeders 51c and 51d from the top in the carrier block D1.

When the resist liquid is supplied from the liquid storage unit 41b disposed above the bottle cart 40 to the liquid feeders 51c and 51d, the pipe length to the liquid feeders 51c and 51d may be reduced, as compared to when the resist liquid is supplied from the liquid storage unit 41a of the bottle cart 40 to the liquid feeders 51c and 51d.

In the embodiment described above, the resist liquid is supplied from one liquid feeder 51 to the two resist film formation modules 21. However, the resist liquid may be supplied from one liquid feeder 51 to one resist film formation module 21. For example, when eight resist film formation modules 21 are provided, eight liquid feeders 51 may be provided corresponding to the resist film formation modules 21, respectively.

While the liquid storage unit 41 illustrated in FIG. 14 is provided as a liquid storage unit 70 equipped with, for example, bottles, assist pumps, and electrical components for operating the assist pumps, the liquid storage unit 70 is not mounted in a cart such as the bottle cart 40. Even in this liquid storage unit 70, the number of bottles may be increased without newly providing a conventional liquid storage unit outside the coating and developing apparatus 1, as long as the liquid storage unit 70 is provided in the interface block D4.

In other words, from the viewpoint of increasing the number of bottles without providing a new liquid storage unit outside the coating and developing apparatus 1, the liquid storage unit 41a of the bottle cart 40 may not necessarily be mounted in the bottle cart 40. That is, the liquid storage unit 41 may be preferably disposed in the interface block D4, and as a result, the number of bottles 42 usable for the resist film formation process may be increased without providing a new liquid storage unit outside the coating and developing apparatus 1.

In the embodiment described above, the processing liquid supplied to the liquid processing module is a resist liquid. However, instead of the resist liquid, a processing liquid for forming a coating film (e.g., an antireflection film) may be used. Further, the processing liquid may be a processing liquid other than a coating liquid.

The effects described herein are merely examples and are not limited. That is, the technology of the present disclosure may achieve other effects obvious to those skilled in the art from the descriptions herein, in addition to or in place of the effects described herein.

Further, the technical scope of the present disclosure also includes the following embodiments.
(1) A substrate processing apparatus including:
a carrier block, into which a carrier storing a substrate is carried;
a processing block including a liquid processing module that supplies a processing liquid to the substrate transferred from the carrier block, thereby performing a liquid processing; and
an interface block, to which the substrate is transferred from the processing block,
wherein the interface block includes a liquid storage, in which a bottle storing the processing liquid is disposed,
the carrier block includes a liquid feeder that feeds the processing liquid supplied from the liquid storage, to the liquid processing module, and
the liquid feeder includes a filter that filters the processing liquid pumped from the liquid storage, and a first pump that pumps the processing liquid toward the liquid processing module.
(2) The substrate processing apparatus of (1) above, wherein the liquid storage is provided in a bottle cart drawable out from the interface block.
(3) The substrate processing apparatus of (2) above, wherein the liquid storage is disposed at one end or both ends of the interface block in a depth direction of the interface block.
(4) The substrate processing apparatus of (3) above, wherein a transfer region is provided inside the interface block to transfer the substrate, and an entry/exit door is provided between the transfer region and the bottle cart, to allow an operator to enter and exit the transfer region.
(5) The substrate processing apparatus of (4) above, wherein a processing module is disposed above the liquid storage, to perform a peripheral exposure processing or a post-exposure cleaning processing on the substrate.
(6) The substrate processing apparatus of (5) above, wherein a rear end of the bottle cart in the depth direction is positioned closer to a front side than a rear end of the processing module in the depth direction is.
(7) The substrate processing apparatus of any one of (2) to (6) above, further including:
a controller configured to control an operation of supplying the processing liquid from the liquid storage to the liquid feeder,
wherein the bottle cart includes
   a second pump that pumps the processing liquid from the liquid storage toward the liquid feeder,
   a cover body that covers a region where the second pump is stored, and
   a detector that detects a mounted state of the cover body, and
the controller is configured to, when the detector detects that the cover body is in a non-mounted state, stop a supply of the processing liquid.
(8) The substrate processing apparatus of any one of (2) to (6) above, wherein above the bottle cart including the liquid storage, another liquid storage is provided.
(9) The substrate processing apparatus of any one of (1) to (8) above, wherein a plurality of liquid processing modules and a plurality of liquid feeders are provided,
an ejector is provided in each of the plurality of liquid processing modules, and
a pipe length from the ejector to the filter on a supply path, through which a resist liquid is supplied to the ejector, is constant.
(10) The substrate processing apparatus of any one of (1) to (9) above, further including:
a liquid feeding unit including the liquid feeder, and an electrical equipment box storing electrical components for operating the liquid feeder,
wherein in the liquid feeding unit, the electrical equipment box is disposed in front of the liquid feeder in a depth direction of the carrier block, and
a mechanism is provided to pivot the electrical equipment box forward in the depth direction of the carrier block.
(11) The substrate processing apparatus of any one of (1) to (9) above, further including:
a liquid feeding unit including the liquid feeder, and an electrical equipment box storing electrical components for operating the liquid feeder,
wherein in the liquid feeding unit, the electrical equipment box is disposed above the liquid feeder, and
a mechanism is provided to slide move the electrical equipment box forward in a depth direction of the carrier block.
(12) The substrate processing apparatus of any one of (1) to (11) above, further including:
a liquid feeding unit including the liquid feeder, and an electrical equipment box storing electrical components for operating the liquid feeder,
wherein in the liquid feeding unit, a mechanism is provided to slide move the liquid feeding unit forward in a depth direction of the carrier block.

According to the present disclosure, without newly providing a liquid storage unit including bottles storing a processing liquid outside a substrate processing apparatus, the number of bottles usable for a liquid processing on a substrate may be increased.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a carrier block into which a carrier storing a substrate is carried;
a processing block including a liquid processing module that supplies a processing liquid to the substrate transferred from the carrier block, thereby performing a liquid processing; and
an interface block to which the substrate is transferred from the processing block,
wherein the interface block includes a liquid storage in which a bottle storing the processing liquid is disposed,
the carrier block includes a liquid feeder that feeds the processing liquid supplied from the liquid storage, to the liquid processing module, and
the liquid feeder includes a filter that filters the processing liquid supplied from the liquid storage, and a first pump that pumps the processing liquid toward the liquid processing module.

2. The substrate processing apparatus according to claim 1, wherein the liquid storage is provided in a bottle cart drawable out from the interface block.

3. The substrate processing apparatus according to claim 2, wherein the liquid storage is disposed at one end or both ends of the interface block in a depth direction of the interface block.

4. The substrate processing apparatus according to claim 3, wherein a transfer region is provided inside the interface block to transfer the substrate, and
an entry/exit door is provided between the transfer region and the bottle cart, to allow an operator to enter and exit the transfer region.

5. The substrate processing apparatus according to claim 4, wherein a processing module is disposed above the liquid storage, to perform a peripheral exposure processing or a post-exposure cleaning processing on the substrate.

6. The substrate processing apparatus according to claim 5, wherein a rear end of the bottle cart in the depth direction of the interface block is positioned closer to a front side than a rear end of the processing module in the depth direction of the interface block is.

7. The substrate processing apparatus according to claim 2, further comprising:
a controller configured to control an operation of supplying the processing liquid from the liquid storage to the liquid feeder,
wherein the bottle cart includes
a second pump that pumps the processing liquid from the liquid storage toward the liquid feeder,
a cover body that covers a region where the second pump is stored, and
a detector that detects a mounted state of the cover body, and
the controller is configured to, when the detector detects that the cover body is in a non-mounted state, stop supplying of the processing liquid.

8. The substrate processing apparatus according to claim 2, wherein above the bottle cart including the liquid storage, another liquid storage is provided.

9. The substrate processing apparatus according to claim 1, wherein a plurality of liquid processing modules and a plurality of liquid feeders are provided,
an ejector is provided in each of the plurality of liquid processing modules, and
a pipe length from the ejector to the filter on a supply path, through which a resist liquid is supplied to the ejector, is constant.

10. The substrate processing apparatus according to claim 1, further comprising:
a liquid feeding unit including the liquid feeder, and an electrical equipment box storing electrical components for operating the liquid feeder,
wherein in the liquid feeding unit, the electrical equipment box is disposed in front of the liquid feeder in a depth direction of the carrier block, and
a mechanism is provided to pivot the electrical equipment box forward in the depth direction of the carrier block.

11. The substrate processing apparatus according to claim 1, further comprising:
a liquid feeding unit including the liquid feeder and an electrical equipment box storing electrical components for operating the liquid feeder,
wherein in the liquid feeding unit, the electrical equipment box is disposed above the liquid feeder, and
a rail is provided to slide move the electrical equipment box forward in a depth direction of the carrier block.

12. The substrate processing apparatus according to claim 1, further comprising:
a liquid feeding unit including the liquid feeder and an electrical equipment box storing electrical components for operating the liquid feeder,
wherein in the liquid feeding unit, a rail is provided to slide move the liquid feeding unit forward in a depth direction of the carrier block.
